(19) United States
(12) Patent Application Publication
(10) Pub. No.: US 2026/0190585 A1
(43) Pub. Date: Jul. 2, 2026

(54) DISPLAY DEVICE

(71) Applicant: LG Display Co., Ltd., Seoul (KR)

(72) Inventors: Changwoo CHUN, Cheonan-si (KR); ByoungHar HWANG, Goyang-si (KR)

(73) Assignee: LG Display Co., Ltd., Seoul (KR)

(21) Appl. No.: 19/409,237

(22) Filed: Dec. 4, 2025

(30) Foreign Application Priority Data
Dec. 30, 2024 (KR) 10-2024-0201241

(51) Int. Cl. H10H 29/854; H10H 29/49; H10H 29/85

(52) U.S. Cl. CPC H10H 29/854; H10H 29/49; H10H 29/8508

(57) ABSTRACT

A display device includes a display panel having a first stretchable substrate, a plurality of sub-pixels spaced apart from each other on the first stretchable substrate, a plurality of stretchable connection lines connecting the sub-pixels, and a second stretchable substrate on the plurality of sub-pixels and the plurality of connection lines. At least one cover substrate is disposed outside the display panel, and the tensile modulus of the cover substrate is higher than the tensile modulus of the first stretchable substrate and the second stretchable substrate. The higher modulus cover substrate provides structural support and protection while allowing the display panel to stretch. This configuration enables the device to maintain durability and stable operation under mechanical deformation while preserving the flexibility required for stretchable display applications.

### CROSS-REFERENCE TO RELATED APPLICATIONS

This application claims the priority of Korean Patent Application No. 10-2024-0201241 filed on Dec. 30, 2024 in the Korean Intellectual Property Office, the disclosure of which is incorporated herein by reference.

### BACKGROUND

### Technical Field

The present disclosure relates to a display device, and more particularly, to a stretchable display device.

### Description of the Related Art

Display devices used for a monitor of a computer, a TV, or a mobile phone include an organic light emitting display (OLED) that emits light by itself, and a liquid crystal display (LCD) that requires a separate light source.

Display devices have been applied in a variety of applications, including computer monitors and TVs as well as personal portable devices, and research is being conducted on display devices that have a large display area and have a reduced volume and weight.

In addition, recently, a display device which is manufactured by forming a display unit, a wiring line, and the like on a flexible substrate such as plastic which is a flexible material to be stretchable in a specific direction and change into various shapes is attracting attention as a next-generation display device.

Since stretchable display devices that can be stretched easily have a property of bending and stretching, they are used for wearable device, new concept furniture, various space utilization and design.

### BRIEF SUMMARY

The disclosed stretchable display device employs a mechanically engineered multi cover substrate architecture in which one or more outer cover substrates possess a substantially higher tensile modulus than the highly flexible stretchable substrates of the display panel. This deliberate modulus hierarchy, which may include first, second, third, and peripheral fourth cover substrates, controls overall elongation, stabilizes the structure under deformation, and positions the neutral plane within the display panel so that sensitive elements such as thin film transistors and micro light emitting diodes experience minimal tensile and compressive stress during bending or stretching. The configuration further incorporates low hysteresis cover materials with a variation of no more than a selected percent (e.g., two percent) to ensure reliable elastic recovery and to avoid cracking or delamination during repeated deformation.

Within the display panel, rigid island regions are used for components that cannot tolerate strain, while serpentine metal interconnects are arranged between the rigid islands to accommodate elongation in a controlled manner. Brittle inorganic layers and light emitting devices are confined to the rigid regions, and a specifically shaped planarization layer reduces stress concentration at the island boundaries. Conductive adhesive bonding allows micro light emitting diodes to be mounted reliably on these rigid regions, and a stretchable touch panel is designed to correspond to the island layout so that sensing films and routing lines remain aligned even when stretched.

In addition, the disclosed device incorporates cover coating layers that include reactive nano crosslinkers to reduce surface tackiness, friction, and scratching while maintaining flexibility and durability. These coating layers enhance handling, improve resistance to external factors, and support consistent performance in wearable and deformable applications. The described structural and material arrangements provide enhanced durability, optical stability, and long term reliability for next generation stretchable display devices.

Various embodiments of the present disclosure provide a stretchable display device in which a surface hardness and a scratch resistance are improved to enhance durability, and a slip characteristic for adjusting a Tacki-less characteristic and a frictional force to reduce surface stickiness is secured, thereby enhancing ease of use.

Various embodiments of the present disclosure provide a stretchable display device which is durable against various mechanical deformations such as stretching, warping, and bending to ensure practicality in a wearable environment and also realizes structural flexibility which can be naturally deformed according to the shape or style of clothes.

Various embodiments of the present disclosure enhance the suitability as a wearable device by developing a surface characteristic in consideration of skin adhesion and wearing sensation, and to improve the overall performance and competitiveness of the product.

Technical benefits of the present disclosure are not limited to the above-mentioned benefits, and other benefits, which are not mentioned above, can be clearly understood by those skilled in the art from the following descriptions.

In order to achieve the benefits as described above, according to an aspect of the present disclosure, a display device includes a display panel comprising a first stretchable substrate, a plurality of sub-pixels spaced apart from each other on the first stretchable substrate, a plurality of stretchable connection lines connecting the sub-pixels, and a second stretchable substrate on the plurality of sub-pixels and the plurality of connection lines, and at least one cover substrate disposed outside the display panel, and the tensile modulus of the cover substrate is higher than that of the first stretchable substrate and the second stretchable substrate.

A display device according to another exemplary embodiment of the present disclosure includes a first cover substrate, a stretchable display panel, a stretchable touch panel on the stretchable display panel, and a second cover substrate on the stretchable touch panel, wherein the tensile modulus of the first cover substrate and the second cover substrate is higher than the tensile modulus of the stretchable substrate included in the stretchable display panel.

Other detailed matters of the embodiments are included in the detailed description and the drawings.

The display device of the present disclosure secures structural stability through a cover substrate having a high tensile modulus and protects internal components from external impacts or pressures. Accordingly, durability of the device is enhanced, and stable performance may be maintained even when used for a long time. In particular, reliability is improved by providing a design suitable for a deformable device such as a wearable device.

Further, the cover coating layer of the present disclosure provides a Tacki-less characteristic which reduces surface stickiness and significantly improves slip characteristic by applying a Nano crosslinker. Through this, it is possible to increase the convenience of handling the device and adaptability to the external environment, and to prevent surface damage that may occur during movement.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view schematically illustrating a display device according to embodiments of the present disclosure.

FIG. 2 is a cross-sectional view taken along line II-II′ illustrated in FIG. 1.

FIG. 3 is a plan view illustrating a display panel included in a display device of FIG. 1.

FIG. 4 is an enlarged plan view illustrating an example of part A of FIG. 3.

FIG. 5 is a cross-sectional view illustrating an example taken along the line V-V′ illustrated in FIG. 4.

FIG. 6 is a plan view for explaining a non-stretched state and a stretched state of a display panel included in a display device of FIG. 1.

FIG. 7A is a graph showing the relationship between tensile deformation and tensile strength of the first cover substrate during tension and contraction.

FIG. 7B is a graph showing the relationship between tensile deformation and tensile strength of the second cover substrate during tension and contraction.

FIG. 8 is a view illustrating a neutral plane of a display device.

FIG. 9 is a cross-sectional view of a display device according to another embodiment of the present disclosure.

FIG. 10 is a plan view schematically illustrating a display device according to embodiments of the present disclosure.

FIG. 11 is a cross-sectional view taken along line X-X′ illustrated in FIG. 10.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “coupled” and “in contact” should be interpreted in the same manner.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

As used herein, the term “footprint” refers to the lateral extent or outline of a layer in a plane parallel to a major surface of the display device, and encompasses the planar area occupied by the layer.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

A display device according to exemplary embodiments of the present disclosure is a display device capable of displaying an image even when it is bent or stretched, and may also be referred to as a stretchable display device, a flexible display device, and a bendable display device. The display device may have high flexibility and stretchability compared to a conventional general display device. Accordingly, the user may bend or stretch the display device, and the shape of the display device may be freely changed according to the user's manipulation. For example, when the user holds and pulls the end of the display device, the display device may be stretched in a direction in which the user pulls the display device. Alternatively, when the user disposes the display device on an uneven outer surface, the display device may be disposed to be bent along the shape of the outer surface of the wall surface. In addition, when the force applied by the user is removed, the display device may be restored to its original shape.

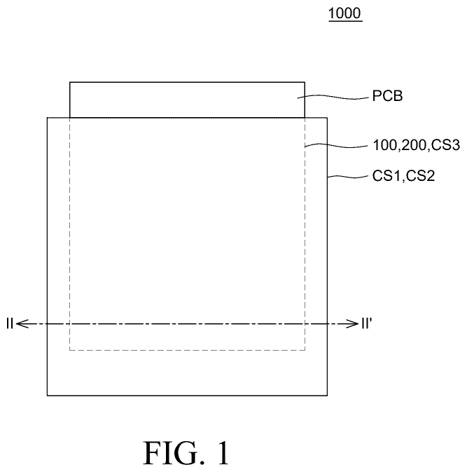

FIG. 1 is a plan view schematically illustrating a display device according to embodiments of the present disclosure.

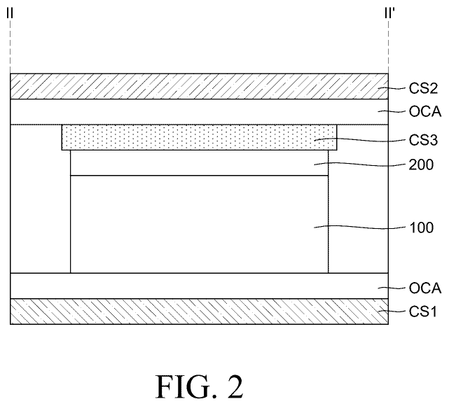

FIG. 2 is a cross-sectional view taken along line II-II′ illustrated in FIG. 1.

Referring to FIGS. 1 and 2, a display device 1000 includes a printed circuit board PCB, a display panel 100, a touch panel 200, a first cover substrate CS1, a second cover substrate CS2, and a third cover substrate CS3.

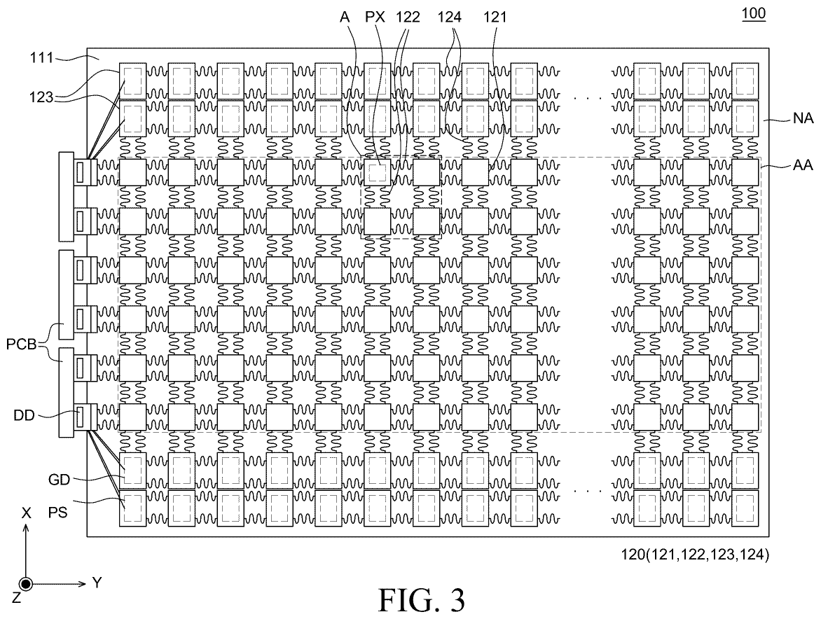

The display panel 100 is stretched even in deformation situations such as stretching and bending, outputs a video and an image, and operates stably. The display panel 100 is stretched, and the distance between pixels is adjusted according to the deformation to maintain consistent image quality. This will be described in detail below with reference to FIGS. 3 to 5.

Touch panel 200 is attached to display panel 100 in an ADD-on manner to detect a user input and convert it into an electrical signal. Touch panel 200 is equipped with a stretchable touch sensor to enable accurate input even in deformation environments such as stretching and bending, and provides high sensitivity and light transmittance by utilizing capacitive touch technology and transparent conductive materials (e.g., graphene or ITO). The ADD-on method of the touch panel 200 secures structural integrity while maintaining the independence of the touch panel and the display panel, and supports multi-touch and gesture recognition. Through this, a precise and reliable user interface is provided in various environments such as wearable devices while maintaining image output quality.

The first cover substrate CS1 protects the display panel 100 and the touch panel 200 from the bottom and provides structural stability. The first cover substrate CS1 is disposed at the lowermost end of the display device 1000 and is bonded to the display panel 100 through the optical adhesive OCA. Further, in FIGS. 1 and 2, the first cover substrate CS1 may be formed wider than that of the display panel 100 and the touch panel 200, but the first cover substrate CS1 may be formed to have the same size as that of the display panel 100 and the touch panel 200.

The second cover substrate CS2 protects upper portions of the display panel 100 and the touch panel 200, protects devices from an external environment, and provides structural stability. The second cover substrate CS2 is disposed on the uppermost end of the display device 1000 and is bonded to the touch panel 200 through the optical adhesive OCA. Further, in FIGS. 1 and 2, the second cover substrate CS2 may be formed wider than that of the display panel 100 and the touch panel 200, but the second cover substrate CS2 may be formed to have the same size as that of the display panel 100 and the touch panel 200.

The third cover substrate CS3 is positioned between the touch panel 200 and the second cover substrate CS2 to protect the intermediate layer and provide structural stability. The third cover substrate CS3 is disposed between the display panel 100 and the touch panel 200 and the second cover substrate CS2 of the display device 1000and is bonded to each component through the optical adhesive OCA. Further, in FIGS. 1 and 2, the third cover substrate CS3 may be formed according to sizes of the display panel 100 and the touch panel 200.

The plurality of cover substrates CS1, CS2, and CS3 may adopt a polymer film or an elastic material to enhance durability and absorb a mechanical shock. Further, the plurality of cover substrates CS1, CS2, and CS3 have light weight and flexibility to maintain stretchable characteristics, and do not affect optical performance by using a transparent material. Through this, the durability of the display device 1000 is increased, and internal components are effectively protected from external impacts or environmental factors.

FIG. 3 is a plan view illustrating a display panel included in a display device of FIG. 1.

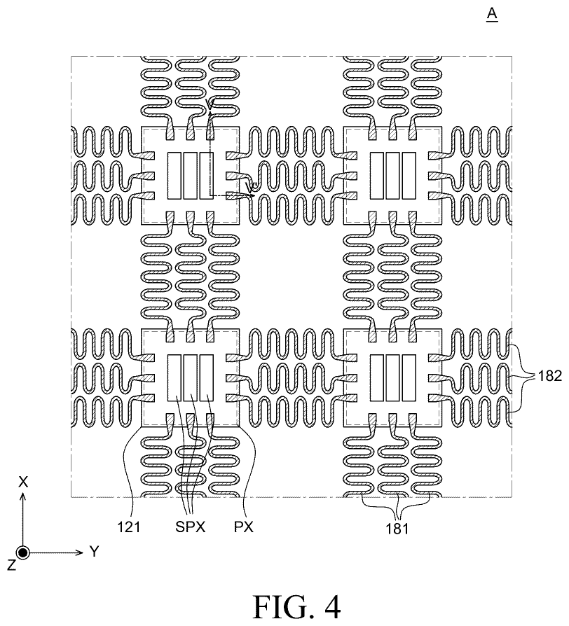

FIG. 4 is an enlarged plan view illustrating an example of part A of FIG. 3.

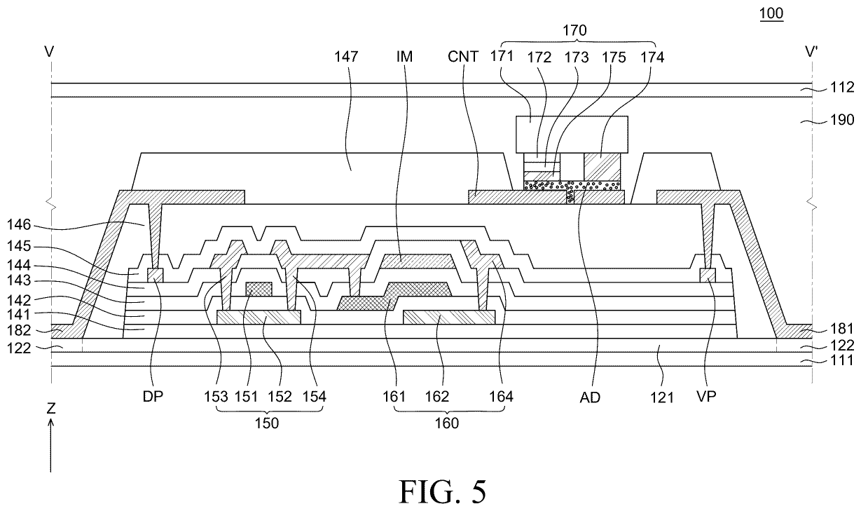

FIG. 5 is a cross-sectional view illustrating an example taken along the line V-V′ illustrated in FIG. 4.

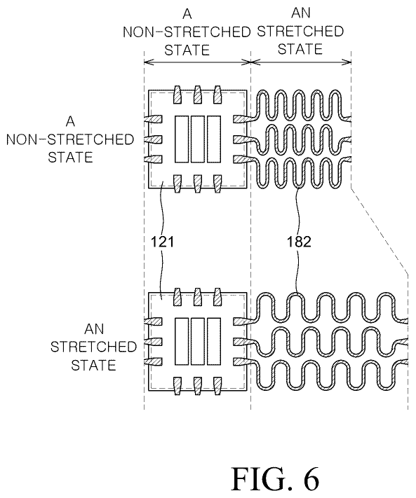

FIG. 6 is a plan view for explaining a non-stretched state and a stretched state of a display panel included in a display device of FIG. 1.

First, referring to FIGS. 3 and 5, the display panel 100 of the present disclosure may include a lower substrate 111, a pattern layer 120, a plurality of pixels PX, a gate driver GD, a data driver DD, a power supply PS, and a printed circuit board PCB. In an embodiment, the display panel 100 may further include an upper substrate 112.

The lower substrate 111 may support the pattern layer 120 on which the pixel PX, the gate driver GD, and the power supply PS are formed, and the upper substrate 112 may be disposed on the lower substrate 111 and cover several components of the display panel 100. In an embodiment, each of the lower substrate 111 and the upper substrate 112 is a flexible substrate and may be formed of an insulating material that may be bent or stretched. Accordingly, the lower substrate 111 may be referred to as a first stretchable substrate.

The tensile modulus of the lower substrate 111 and the upper substrate 112 may be equal to or less than 1 MPa. Further, a ductile breaking rate of the lower substrate 111 and the upper substrate 112 may be 100% or higher. Here, the ductile failure rate means the elongation rate at the time when the object to be stretched is destroyed or cracked.

The lower substrate 111 may include an active area AA (or a display area) and a non-active area NA (or a non-display area) excluding the active area AA. For example, the inactive area NA may surround the active area AA.

A plurality of pixels PX each including a display element and a circuit element may be disposed in the active area AA.

A gate driver GD and a power supply PS for driving a plurality of pixels PX disposed in the active area AA may be disposed in the inactive area NA.

The pattern layer 120 may be disposed on the lower substrate 111.

In an embodiment, the pattern layer 120 may include a plurality of first plate patterns 121 and a plurality of first line patterns 122 disposed in the active area AA, a plurality of second plate patterns 123 and a plurality of second line patterns 124 disposed in the inactive area NA.

The plurality of first plate patterns 121 is disposed in the active area AA of the lower substrate 111, and a plurality of pixels PX may be formed on the plurality of first plate patterns 121. The plurality of second plate patterns 123 is disposed in the inactive area NA of the lower substrate 111, and the gate driver GD and the power supply PS may be formed on the plurality of second plate patterns 123.

Further, even though in FIG. 3, it is illustrated that the plurality of first plate patterns 121 and the plurality of second plate patterns 123 have a rectangular shape, it is not limited thereto and may be modified into various shapes.

Referring to FIG. 3, the pattern layer 120 may further include a plurality of first line patterns 122 disposed in the active area AA and a plurality of second line patterns 124 disposed in the inactive area NA.

The plurality of first line patterns 122 is patterns which are disposed in the active area AA and connect the first plate patterns 121 adjacent to each other and may be referred to as first connection patterns.

The plurality of second line patterns 124 may be patterns which are disposed in the non-active area NA and connect the first plate pattern 121 and the second plate pattern 123 adjacent to each other or connect the plurality of second plate patterns 123 adjacent to each other.

Referring to FIG. 3, the plurality of first line patterns 122 and the second line pattern 124 may have a curved shape (e.g., a sinusoidal shape), but are not limited thereto. The plurality of first line patterns 122 and the second line pattern 124 may have various shapes, such as extending in a zigzag shape or extending by connecting a plurality of rhombic substrates at vertices.

In an embodiment, the plurality of first plate patterns 121, the plurality of first line patterns 122, the plurality of second plate patterns 123, and the plurality of second line patterns 124 may be rigid patterns. That is, the plurality of first plate patterns 121, the plurality of first line patterns 122, the plurality of second plate patterns 123, and the plurality of second line patterns 124 may be rigid compared to the lower substrate 111 and the upper substrate 112 to be described later. Accordingly, the tensile modulus of the plurality of first plate patterns 121, the plurality of first line patterns 122, the plurality of second plate patterns 123, and the plurality of second line patterns 124 may be higher than the tensile modulus of the lower substrate 111 and the upper substrate 112. The tensile modulus of the plurality of first plate patterns 121, the plurality of first line patterns 122, the plurality of second plate patterns 123, and the plurality of second line patterns 124 may be 1000 times higher than that of the lower substrate 111 and the upper substrate 112, but is not limited thereto.

The plurality of first plate patterns 121, the plurality of first line patterns 122, the plurality of second plate patterns 123, and the plurality of second line patterns 124, which are the plurality of rigid substrates, may be formed of a plastic material having lower flexibility than the lower substrate 111 and the upper substrate 112 to be described later.

The gate driver GD may supply a gate signal to the plurality of pixels PX disposed in the active area AA. The gate driver GD includes a plurality of stages formed on the plurality of second plate patterns 123, and each stage of the gate driver GD may be electrically connected to each other through a plurality of gate connection lines. Accordingly, the gate signal output from one stage may be transmitted to the other stage. Each stage may sequentially supply gate signals to a plurality of pixels PX connected to each stage.

The power supply PS may be connected to the gate driver GD to supply a gate driving voltage and a gate clock voltage. Further, the power supply PS is connected to the plurality of pixels PX to supply a pixel driving voltage to each of the plurality of pixels PX.

The printed circuit board PCB may include a control unit such as an IC chip, a circuit unit, etc., and/or a memory, a processor, etc., to transmit signals and voltages for driving the display element from the control unit to the display element. The printed circuit board PCB may include a stretchable area and a non-stretchable area to ensure stretchability. For example, an IC chip, a circuit unit, a memory, a processor, etc., may be mounted in the non-stretching area, and wiring lines electrically connected to the IC chip, the circuit unit, the memory, and the processor may be disposed in the stretching area.

The data driver DD may supply a data voltage to the plurality of pixels PX disposed in the active area AA. The data driver DD may be mounted in the non-stretching area of the printed circuit board PCB.

Referring to FIGS. 3 and 4, a plurality of first plate patterns 121 may be disposed in the active area AA of the lower substrate 111. The plurality of first plate patterns 121 may be spaced apart from each other and disposed on the lower substrate 111. For example, as illustrated in FIG. 3, the plurality of first plate patterns 121 may be disposed in a matrix form on the lower substrate 111, but is not limited thereto.

Referring to FIG. 4, a pixel PX including a plurality of sub-pixels SPX may be disposed in the first plate pattern 121. Each sub pixel SPX may include an LED 170 which is a display element, and a driving transistor 160 and a switching transistor 150 for driving the LED 170. However, in the sub pixel SPX, the display element is not limited to an LED, but may be changed to an organic light emitting diode.

The plurality of sub-pixels SPX may include a red sub-pixel, a green sub-pixel, and a blue sub-pixel, but is not limited thereto, and the colors of the plurality of sub-pixels SPX may be variously modified as necessary.

The plurality of sub pixels SPX may be connected to the plurality of connection lines 181 and 182.

Hereinafter, a cross-sectional structure of the display panel 100 in the active area AA will be described in more detail with reference to FIG. 5.

Referring to FIG. 5, a plurality of inorganic insulating layers may be disposed on a plurality of first plate patterns 121. For example, the plurality of inorganic insulating layers may include a buffer layer 141, a gate insulating layer 142, a first interlayer insulating layer 143, a second interlayer insulating layer 144, and a passivation layer 145. However, the present disclosure is not limited thereto. Various inorganic insulating layers may be additionally disposed on the plurality of first plate patterns 121 or one or more of a buffer layer 141, a gate insulating layer 142, a first interlayer insulating layer 143, a second interlayer insulating layer 144, and a passivation layer 145 which are inorganic insulating layers may be omitted.

The buffer layer 141 may be disposed on the plurality of first plate patterns 121. The buffer layer 141 includes an insulating material and may be formed on the plurality of first plate patterns 121 to protect various components of the display panel 100 from permeation of moisture (H₂O) and oxygen (O₂) from the outside of the lower substrate 111 and the plurality of first plate patterns 121. However, the buffer layer 141 may be omitted depending on the structure or characteristics of the display panel 100.

In an embodiment, the buffer layer 141 may be formed only in an area in which the lower substrate 111 overlaps the plurality of first plate patterns 121 and the plurality of second plate patterns 123. As described above, the buffer layer 141 may be formed of an inorganic material so that the buffer layer 141 may be easily cracked or damaged during the process of stretching the display panel 100. Therefore, the buffer layer 141 is not formed in an area between the plurality of first plate patterns 121 and the plurality of second plate patterns 123, but is patterned to have shapes of the plurality of first plate patterns 121 and the plurality of second plate patterns 123 to be formed only on the plurality of first plate patterns 121 and the plurality of second plate patterns 123. Accordingly, in the case of the display panel 100 according to the exemplary embodiment of the present disclosure and the display device 1000 including the same, the buffer layer 141 is formed only in an area overlapping the plurality of first plate patterns 121 and the plurality of second plate patterns 123 which are rigid patterns. Therefore, even when the display panel 100 is deformed such as being bent or stretched, damage to various components of the display panel 100 may be prevented.

Referring to FIG. 5, a switching transistor 150 including a gate electrode 151, an active layer 152, a source electrode 153, and a drain electrode 154 and a driving transistor 160 including a gate electrode 161, an active layer 162, a source electrode, and a drain electrode 164 may be disposed on the buffer layer 141.

The active layer 152 of the switching transistor 150 and the active layer 162 of the driving transistor 160 may be disposed on the buffer layer 141. For example, each of the active layer 152 of the switching transistor 150 and the active layer 162 of the driving transistor 160 may be formed of an oxide semiconductor, amorphous silicon (a-Si), polycrystalline silicon (poly-Si), or an organic semiconductor.

A gate insulating layer 142 may be disposed on the active layer 152 of the switching transistor 150 and the active layer 162 of the driving transistor 160. The gate insulating layer 142 includes an insulating material and may electrically insulate the gate electrode 151 of the switching transistor 150 and the active layer 152 of the switching transistor 150 and electrically insulate the gate electrode 161 of the driving transistor 160 and the active layer 162 of the driving transistor 160.

The gate electrode 151 of the switching transistor 150 and the gate electrode 161 of the driving transistor 160 may be disposed on the gate insulating layer 142. The gate electrode 151 of the switching transistor 150 and the gate electrode 161 of the driving transistor 160 may be disposed on the gate insulating layer 142 to be spaced apart from each other. Further, the gate electrode 151 of the switching transistor 150 may overlap the active layer 152 of the switching transistor 150, and the gate electrode 161 of the driving transistor 160 may overlap the active layer 162 of the driving transistor 160.

A first interlayer insulating layer 143 may be disposed on the gate electrode 151 of the switching transistor 150 and the gate electrode 161 of the driving transistor 160. The first interlayer insulating layer 143 includes an insulating material and may insulate the gate electrode 161 of the driving transistor 160 from the intermediate metal layer IM.

An intermediate metal layer IM including a metal material may be disposed on the first interlayer insulating layer 143. The intermediate metal layer IM may overlap the gate electrode 161 of the driving transistor 160. Therefore, a storage capacitor may be formed in an overlapping region between the intermediate metal layer IM and the gate electrode 161 of the driving transistor 160. For example, the gate electrode 161, the first interlayer insulating layer 143, and the intermediate metal layer IM of the driving transistor 160 may form a storage capacitor. However, the arrangement area of the intermediate metal layer IM is not limited thereto, and the intermediate metal layer IM overlaps the other electrodes to form various storage capacitors.

The second interlayer insulating layer 144 may be disposed on the intermediate metal layer IM. The second interlayer insulating layer 144 includes an insulating material and may insulate the gate electrode 151 of the switching transistor 150 from the source electrode 153 and the drain electrode 154 of the switching transistor 150. Further, the second interlayer insulating layer 144 may insulate the intermediate metal layer IM from the source electrode and the drain electrode 164 of the driving transistor 160.

The source electrode 153 and the drain electrode 154 of the switching transistor 150 may be disposed on the second interlayer insulating layer 144. Further, a source electrode and a drain electrode 164 of the driving transistor 160 may be disposed on the second interlayer insulating layer 144. The source electrode 153 and the drain electrode 154 of the switching transistor 150 may be disposed to be spaced apart from each other on the same layer.

Meanwhile, in FIG. 5, the source electrode of the driving transistor 160 is omitted, but the source electrode of the driving transistor 160 may also be disposed to be spaced apart from the drain electrode 164 on the same layer. In the switching transistor 150, the source electrode 153 and the drain electrode 154 may be electrically connected to the active layer 152 in such a manner as to be in contact with the active layer 152. Further, in the driving transistor 160, the source electrode and the drain electrode 164 may be electrically connected to the active layer 162 in such a manner as to be in contact with the active layer 162. Further, the drain electrode 154 of the switching transistor 150 may be electrically connected to the gate electrode 161 of the driving transistor 160 by contacting the gate electrode 161 of the driving transistor 160 through a contact hole.

A gate pad, a data pad DP, and a voltage pad VP may be disposed on the second interlayer insulating layer 144.

Specifically, the gate pad may transmit a gate signal to the plurality of sub pixels SPX. The gate pad may be connected to the first connection line 181 through a contact hole. Further, the gate signal supplied from the first connection line 181 may be transmitted from the gate pad to the gate electrode 151 of the switching transistor 150 through a line formed on the first plate pattern 121.

The data pad DP may transmit a data voltage to the plurality of sub pixels SPX. The data pad DP may be connected to the second connection line 182 through a contact hole. Further, the data voltage supplied from the second connection line 182 may be transmitted from the data pad DP to the source electrode 153 of the switching transistor 150 through a line formed on the first plate pattern 121.

Further, the voltage pad VP may transmit a low-potential voltage to the plurality of sub-pixels SPX. The voltage pad VP may be connected to the first connection line 181 through a contact hole. Further, the low-potential voltage supplied from the first connection line 181 may be transmitted from the voltage pad VP to the n-electrode 174 of the LED 170 through a line formed on the first plate pattern 121.

The gate pad and the data pad DP may be formed of the same material as the source electrode 153 and the drain electrodes 154 and 164, but are not limited thereto.

A passivation layer 145 may be formed on the switching transistor 150 and the driving transistor 160. That is, the passivation layer 145 may be disposed to cover the switching transistor 150 and the driving transistor 160 to protect the switching transistor 150 and the driving transistor 160 from the penetration of moisture and oxygen. The passivation layer 145 may be formed of an inorganic material, and may be formed of a single layer or a double layer, but is not limited thereto.

Further, the gate insulating layer 142, the first interlayer insulating layer 143, the second interlayer insulating layer 144, and the passivation layer 145 are patterned to be formed only in an area overlapping the plurality of first plate patterns 121. The gate insulating layer 142, the first interlayer insulating layer 143, the second interlayer insulating layer 144, and the passivation layer 145 may also be made of an inorganic material in the same manner as the buffer layer 141. Therefore, the gate insulating layer 142, the first interlayer insulating layer 143, the second interlayer insulating layer 144, and the passivation layer 145 may be easily damaged, such as cracking easily during the process of stretching the display panel 100 or the display device 1000. Therefore, the gate insulating layer 142, the first interlayer insulating layer 143, the second interlayer insulating layer 144, and the passivation layer 145 are not formed in an area between the plurality of first plate patterns 121, but are patterned in the shape of the plurality of first plate patterns 121 to be formed only above the plurality of first plate patterns 121.

A planarization layer 146 may be formed on the passivation layer 145. The planarization layer 146 may planarize upper portions of the switching transistor 150 and the driving transistor 160. The planarization layer 146 may be configured by a single layer or a plurality of layers, and may be formed of an organic material.

The planarization layer 146 may be disposed on the plurality of first plate patterns 121 to cover upper and side surfaces of the buffer layer 141, the gate insulating layer 142, the first interlayer insulating layer 143, the second interlayer insulating layer 144, and the passivation layer 145. Further, the planarization layer 146 may be disposed to surround the buffer layer 141, the gate insulating layer 142, the first interlayer insulating layer 143, the second interlayer insulating layer 144, and the passivation layer 145 together with the plurality of first plate patterns 121. Specifically, the planarization layer 146 may be disposed to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of first plate patterns 121. Therefore, the planarization layer 146 may compensate for a step on the side surfaces of the buffer layer 141, the gate insulating layer 142, the first interlayer insulating layer 143, the second interlayer insulating layer 144, and the passivation layer 145. Further, the planarization layer 146 may increase an adhesive strength with the connection lines 181 and 182 disposed on the side surface of the planarization layer 146.

The inclination angle of the side surface of the planarization layer 146 may be smaller than the inclination angle formed by the side surfaces of the buffer layer 141, the gate insulating layer 142, the first interlayer insulating layer 143, the second interlayer insulating layer 144, and the passivation layer 145. For example, the side surface of the planarization layer 146 may have an inclination gentler than an inclination formed by each of the side surface of the passivation layer 145, the side surface of the first interlayer insulating layer 143, the side surface of the second interlayer insulating layer 144, the side surface of the gate insulating layer 142, and the side surface of the buffer layer 141. Therefore, the connection lines 181 and 182 which are disposed to be in contact with the side surface of the planarization layer 146 is disposed with a gentle slope so that when the display panel 100 is stretched, the stress generated in the connection lines 181 and 182 may be reduced. Further, the side surface of the planarization layer 146 has a relatively gentle slope so that the crack of the connection lines 181 and 182 or the separation of the side surface of the planarization layer 146 may be suppressed.

Referring to FIGS. 4 and 5, the connection lines 181 and 182 may electrically connect pads on the plurality of first plate patterns 121. The connection lines 181 and 182 may be disposed on the plurality of first line patterns 122. Further, the connection lines 181 and 182 may extend even on the plurality of first plate patterns 121 to be electrically connected to the gate pads and the data pads DP on the plurality of first plate patterns 121. Further, the first line pattern 122 may not be disposed in an area in which the connection lines 181 and 182 are not disposed, among areas between the plurality of first plate patterns 121.

The connection lines 181 and 182 may include a first connection line 181 and a second connection line 182. The first connection line 181 and the second connection line 182 may include a metal material and may be disposed between the plurality of first plate patterns 121.

More specifically, the first connection line 181 refers to a line extending in the first direction X between the plurality of first plate patterns 121 among the connection lines 181 and 182. The second connection line 182 may be a line extending in the second direction Y between the plurality of first plate patterns 121 among the connection lines 181 and 182.

Meanwhile, in the case of a display panel of a general display device, various wiring lines, such as a plurality of gate lines and a plurality of data lines, are disposed to extend in a straight line shape between the plurality of sub pixels, and a plurality of sub pixels are connected to one signal line. Accordingly, in the case of a display panel of a general display device, various wiring lines such as a gate line, a data line, a high potential voltage line, and a reference voltage line are disconnected on the substrate. Without it, it extends from one side of the display panel of the organic light emitting display device to the other side.

Alternatively, in the case of the display panel 100 included in the display device 1000 according to the exemplary embodiment of the present disclosure, various wiring lines, such as a straight gate line, a data line, a high potential voltage line, a reference voltage line, and an initialization voltage line, which may be considered to be used in the display panel of a general display device, may be disposed only on the plurality of first plate patterns 121 and the plurality of second plate patterns 123. That is, in the display panel 100 included in the display device 1000 according to the exemplary embodiment of the present disclosure, straight lines may be disposed only on the plurality of first plate patterns 121 and the plurality of second plate patterns 123.

In the display panel 100 of the display device 1000according to the exemplary embodiment of the present disclosure, pads on two adjacent first plate patterns 121 may be connected by the connection lines 181 and 182. Accordingly, the connection lines 181 and 182 may electrically connect the gate pad or the data pad DP on the two adjacent first plate patterns 121. Accordingly, the display panel 100 included in the display device 1000 according to the exemplary embodiment of the present disclosure may include a plurality of connection lines 181 and 182 to electrically connect various wiring lines, such as a gate line, a data line, a high potential voltage line, and a reference voltage line, between the plurality of first plate patterns 121. For example, a gate line may be disposed on the plurality of first plate patterns 121 disposed adjacent to each other in the first direction X, and gate pads may be disposed at both ends of the gate line. In this case, each of the plurality of gate pads on the plurality of first plate patterns 121 disposed adjacent to each other in the first direction X may be connected to each other by the first connection line 181 functioning as a gate line. Therefore, the gate line disposed on the plurality of first plate patterns 121 and the first connection line 181 disposed on the first line pattern 122 may function as one gate line. The above-described gate wiring may be referred to as a scan signal wiring. Further, among all various wiring lines which may be included in the display panel 100, wiring lines which extend in the first direction X, for example, an emission signal line, a low potential voltage line, and a high potential voltage line, may also be electrically connected by the first connection line 181 as described above.

Referring to FIGS. 3 and 4, the first connection line 181 may connect gate pads on two first plate patterns 121 disposed side by side, among gate pads on a plurality of first plate patterns 121 disposed adjacent to each other in the first direction X. The first connection line 181 may function as a gate line, an emission signal line, a high potential voltage line, or a low potential voltage line, but is not limited thereto. The gate pads on the plurality of first plate patterns 121 disposed in the first direction X may be connected by the first connection line 181 functioning as a gate line, and one gate voltage may be transmitted.

Further, referring to FIGS. 3 and 4, the second connection line 182 may connect the data pads DP on two first plate patterns 121 disposed side by side, among the data pads DP on the plurality of first plate patterns 121 disposed to be adjacent in the second direction Y. The second connection line 182 may function as a data line, a high potential voltage line, a low potential voltage line, or a reference voltage line, but is not limited thereto. Internal lines on the plurality of first plate patterns 121 disposed in the second direction Y may be connected by the plurality of second connection lines 182 functioning as data lines, and one data voltage may be transmitted.

Meanwhile, referring to FIG. 5, a bank 147 may be formed on the connection pad CNT, the connection lines 181 and 182, and the planarization layer 146. The bank 147 includes an insulating material and may distinguish adjacent sub pixels SPX. The bank 147 may be disposed to cover at least a part of the connection lines 181 and 182 and the planarization layer 146. Even though in FIG. 4, it is illustrated that the height of the bank 147 is lower than the height of the LED 170, it is not limited thereto and the height of the bank 147 may be equal to the height of the LED 170.

The LED 170 may be disposed on the connection pad CNT and the first connection line 181. The LED 170 may include an n-type layer 171, an active layer 172, a p-type layer 173, an n-electrode 174, and a p-electrode 175. The LED 170 of the display panel 100 according to the exemplary embodiment of the present disclosure may have a flip-chip structure in which the n electrode 174 and the p electrode 175 are formed on one side, but is not limited thereto.

The n-type layer 171 may be formed by implanting an n-type impurity into gallium nitride (GaN) having excellent crystallinity. The n-type layer 171 may be disposed on a separate base substrate made of a material capable of emitting light.

The active layer 172 may be disposed on the n-type layer 171. The active layer 172 is a light emitting layer which emits light from the LED 170 and may be formed of a nitride semiconductor, for example, indium gallium nitride (InGaN). A p-type layer 173 may be disposed on the active layer 172. The p-type layer 173 may be formed by implanting p-type impurities into gallium nitride (GaN).

As described above, the LED 170 according to an embodiment of the present disclosure may be manufactured by sequentially stacking the n-type layer 171, the active layer 172, and the p-type layer 173, etching a predetermined portion, and then forming the n-electrode 174 and the p-electrode 175. In this case, the predetermined portion is a space for separating the n-electrode 174 and the p-electrode 175, and the predetermined portion may be etched to expose a part of the n-type layer 171. In other words, the surface of the LED 170 on which the n electrode 174 and the p electrode 175 are to be disposed may have different height levels than the planarized surface.

In this way, the n electrode 174 is disposed in the etched area, and the n electrode 174 may be formed of a conductive material. Further, the p-electrode 175 is disposed in the non-etched region, and the p-electrode 175 may also be formed of a conductive material. For example, the n-electrode 174 may be disposed on the n-type layer 171 exposed by the etching process, and the p-electrode 175 may be disposed on the p-type layer 173. The p electrode 175 may be formed of the same material as the n electrode 174.

The conductive adhesive layer AD may be disposed between a top surface of the connection pad CNT and the LED 170 and between a top surface of the first connection line 181 and the LED 170, such that the LED 170 may be bonded onto the connection pad CNT and the first connection line 181. In this case, the n-electrode 174 may be disposed on the first connection line 181, and the p-electrode 175 may be disposed on the connection pad CNT.

The conductive adhesive layer AD may be an adhesive layer having conductivity by dispersing conductive balls in an insulating base member. Accordingly, when heat or pressure is applied to the conductive adhesive layer AD, the conductive balls are electrically connected in a portion to which heat or pressure is applied to have a conductive property, and an area to which heat or pressure is not applied may have an insulating property. For example, the n-electrode 174 may be electrically connected to the first connection line 181 through the conductive adhesive layer AD, and the p-electrode 175 may be electrically connected to the connection pad CNT through the conductive adhesive layer AD. After applying the conductive adhesive layer AD on the top surfaces of the first connection line 181 and the connection pad CNT by an inkjet method, the LED 170 is transferred onto the conductive adhesive layer AD, and the connection pad CNT, the p electrode 175, and the n electrode 174 may be electrically connected by pressurizing and heating the LED 170. However, portions of the conductive adhesive layer AD other than portions of the conductive adhesive layer AD disposed between the n electrode 174 and the first connection line 181 and portions of the conductive adhesive layer AD disposed between the p electrode 175 and the connection pad CNT may have insulating properties. Meanwhile, the conductive adhesive layer AD may be disposed on each of the connection pad CNT and the first connection line 181 in a separated form.

Further, the connection pad CNT is electrically connected to the drain electrode 164 of the driving transistor 160 to receive a driving voltage for driving the LED 170 from the driving transistor 160. FIG. 4 illustrates that the connection pad CNT is not in direct contact with the drain electrode 164 of the driving transistor 160, but is not limited thereto, and the connection pad CNT and the drain electrode 164 of the driving transistor 160 may be in direct contact with each other. Further, a low potential driving voltage for driving the LED 170 may be applied to the first connection line 181. Therefore, when the display panel 100 is turned on, different voltage levels applied to the connection pad CNT and the first connection line 181 are transmitted to the n electrode 174 and the p electrode 175, respectively, so that the LED 170 may emit light.

The upper substrate 112 supports various components disposed below the upper substrate 112. The upper substrate 112 may be a substrate for covering and protecting various components of the display panel 100. For example, the upper substrate 112 may be a substrate covering the pixel PX, the gate driver GD, and the power supply PS which are components of the display panel 100. Accordingly, the upper substrate 112 may be referred to as a second stretchable substrate.

Further, a filling layer 190 which is disposed on the front surface of the lower substrate 111 to fill a space between the upper substrate 112 and components disposed on the lower substrate 111 may be disposed. The filling layer 190 may be formed of a curable adhesive. Specifically, the material constituting the filling layer 190 is coated on the front surface of the lower substrate 111 and then cured, such that the filling layer 190 may be disposed between the upper substrate 112 and the components disposed on the lower substrate 111. For example, the filling layer 190 may be an optically clear adhesive (OCA) and may be composed of an acrylic adhesive, a silicone adhesive, a urethane adhesive, or the like.

Further, referring to FIG. 2, the touch panel 200 may include a material capable of responding to the stretching of the display panel 100. The touch panel 200 may be disposed above the display panel 100 and may have a shape corresponding to the display panel 100, for example, a shape corresponding to the lower substrate 111 supporting the display panel 100.

For example, the touch panel 200 may include a base substrate (or a touch base substrate), a plurality of touch sensing films disposed on the base substrate, a plurality of touch lines arranged in different directions on the base substrate and the plurality of touch sensing films, a plurality of routing lines connected to the plurality of touch lines to transmit a touch signal detected by the plurality of touch lines, and a plurality of link lines connected to the plurality of routing lines and the touch circuit unit.

The base substrate may support a plurality of touch sensing films, a plurality of touch lines, a plurality of routing lines, and a plurality of link lines. The base substrate is a flexible substrate, and may be reversibly expanded and contracted.

The plurality of touch sensing films may be disposed to be spaced apart from each other by a predetermined distance on the active area AA of the base substrate. In an embodiment, the size of each of the plurality of touch sensing films may correspond to the size of each of the plurality of first plate patterns 121 disposed on the display panel 100 described with reference to FIG. 3. In an embodiment, the plurality of touch sensing films may include a touch sensing material. For example, the plurality of touch sensing films may include a touch base film made of an insulating material that may be bent or stretched, and a touch sensing material dispersed in a particle format in the touch base film, but is not limited thereto.

A plurality of touch lines for sensing a touch may be disposed below and above the touch sensing film.

The plurality of touch lines may include a plurality of first touch lines disposed in the first direction X in the active area AA of the base substrate, and a plurality of second touch lines disposed in the second direction Y so as to intersect the plurality of first touch lines with the touch sensing film therebetween. An area where the plurality of first touch lines and the plurality of second touch lines intersect is defined as a touch sensing area, and the plurality of touch sensing films may be disposed to overlap the touch sensing area. Accordingly, the touch panel 200 may detect the touch coordinates and the touch pressure by using a change in resistance of the touch sensing film with respect to the touch input.

The plurality of touch wirings may have a linear shape in an area (e.g., a touch sensing area) overlapping the plurality of touch sensing films, and may have a curved shape in other areas.

As described above, a plurality of touch sensing films of the touch panel 200 of the display panel 100 according to the exemplary embodiments of the present disclosure are disposed on a base substrate which is a flexible substrate so as to be spaced apart from each other and disposed in an area overlapping the first plate pattern 121 of the display panel 100. Thus, when the display panel 100 is bi-directionally stretched, the touch panel 200 may also be bi-directionally stretched.

The plurality of routing lines may be disposed on the inactive area NA of the base substrate, and may be connected to the plurality of touch lines disposed in the active area AA. Accordingly, a touch signal detected by a plurality of touch lines may be transmitted to a plurality of routing lines.

The plurality of routing lines may have a curved shape to ensure the stretchability of the touch panel 200.

The plurality of link lines may electrically connect the plurality of routing lines and the touch circuit unit. Accordingly, the touch signal detected from the plurality of touch lines and transmitted to the plurality of routing lines may be transmitted to the touch circuit unit through the plurality of link lines. Accordingly, the touch circuit unit may detect a touch (e.g., a user's touch) input from the outside.

Referring to FIG. 2, the display device 1000 of the present disclosure includes a first cover substrate CS1, a second cover substrate CS2, a third cover substrate CS3, a display panel 100, and a touch panel 200. Further referring to FIG. 5, the tensile modulus of each of the cover substrates CS1, CS2, and CS3 is higher than that of the upper substrate 112 and the lower substrate 111 of the display panel 100. For example, the tensile modulus of the cover substrates CS1, CS2, and CS3 may be 1 MPa or more, but the tensile modulus of the upper substrate 112 and the lower substrate 111 may be less than 1 MPa. This configuration protects internal components of the display device 1000 and provides structural stability.

Referring to FIG. 6, the display panel 100 is divided into a non-stretching area in which a first plate pattern 121 in which pixels are located is disposed and a stretching area in which a first connection line 181 or a second connection line 182 is disposed. The non-stretching area does not change in the stretching length even in the non-stretching state and the stretching state, and maintains a stable shape. On the other hand, in the stretchable area, there is a difference in the stretchable length in the non-stretched state and the stretched state, and the stretchable characteristics of the display panel 100 are implemented.

Since the tensile modulus of each of the cover substrates CS1, CS2, and CS3 is higher than that of the upper substrate 112 and the lower substrate 111 of the display panel 100, the elongation of the stretchable area may be limited. For example, the stretchable area has an elongation of about 140%, and the elongation of the display panel 100 is designed to be about 120%, ensuring stable performance even in mechanical deformation.

In other words, the high tensile modulus of the first cover substrate CS1, the second cover substrate CS2, and the third cover substrate CS3 effectively protects each component of the display device 1000 from external impacts and deformations. This stability contributes to enhancing the durability of the device and increasing reliability when used for a long time.

By limiting the elongation of the stretchable area to about 140%, it is possible to control the display device 1000 so that it is not damaged due to excessive deformation. This is a key element of a stretchable display, ensuring stable performance and long life.

As the total elongation is set to be about 120%, the display device 1000 provides flexibility and reliability suitable for deformable electronic devices such as wearable devices. Accordingly, the performance of the display device 1000 is uniformly maintained and may be applied in various forms according to the user's request.

In conclusion, the display device 1000 of the present disclosure simultaneously implements structural stability, stretchable characteristics, and durability through the control of the high tensile modulus cover substrates CS1, CS2, and CS3 and the stretching region 182. Through this, it is possible to provide optimal performance and reliability in various application fields such as wearable devices.

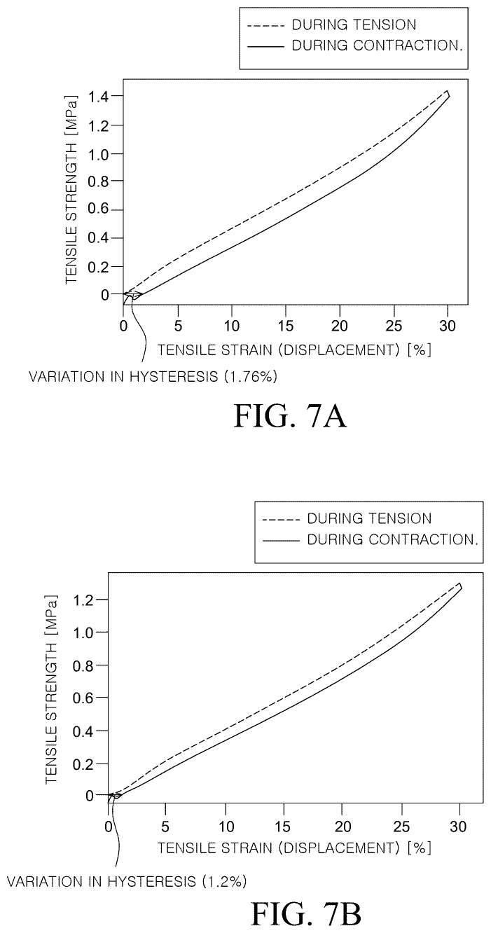

FIG. 7A is a graph showing the relationship between tensile deformation and tensile strength of the first cover substrate during tension and contraction.

FIG. 7B is a graph showing the relationship between tensile deformation and tensile strength of the second cover substrate during tension and contraction.

The display device 1000 of the present disclosure is designed based on the respective characteristics by analyzing tensile deformation characteristics and tensile strength of the first cover substrate CS1 and the second cover substrate CS2 at the time of tensile and contraction.

Specifically, in order to set the overall elongation to be about 120%, the variation of hysteresis affecting the elastic restoring force during tension and contraction of the first cover substrate CS1 and the second cover substrate CS2 may be within 2%. Specifically, when the variation of the hysteresis of each of the first cover substrate CS1 and the second cover substrate CS2 is high, it may mean that the elastic restoring force when each of the first cover substrate CS1 and the second cover substrate CS2 is stretched and contracted decreases. For example, when the variation of hysteresis of each of the first cover substrate CS1 and the second cover substrate CS2 is 2% or more, when the stretching of the display device 1000 of the present disclosure is repeated, there may be a problem in that the first cover substrate CS1 and the second cover substrate CS2 are not completely contracted, causing deformation or cracking of the connection line. Accordingly, the amount of change in hysteresis of each of the first cover substrate CS1 and the second cover substrate CS2 of the display device 1000 of the present disclosure must be 2% or less.

The tensile modulus of the first cover substrate CS1 may be higher than that of the second cover substrate CS2. Further, the tensile modulus of the first cover substrate CS1 and the tensile modulus of the second cover substrate CS2 may be 3.0 MPa to 7.0 MPa.

On the premise of this, referring to FIG. 7A, as indicated by a dotted line, as the tensile strength of the first cover substrate CS1 increases during tension, the degree of tensile deformation increases. Specifically, the tensile strength increases from 0 MPa to 1.2 Mpa or more during tension, and accordingly, the degree of tensile deformation may also increase to 30%. In contrast, referring to FIG. 7A, as indicated by a solid line, the degree of tensile deformation decreases as the tensile strength decreases during the contraction of the first cover substrate CS1. Specifically, the tensile strength decreases from 1.2 Mpa or more to 0 MPa during tension, and accordingly, the degree of tensile deformation may gradually decrease. However, as shown in FIG. 7A, even if the tensile strength becomes 0 MPa during contraction, the degree of tensile deformation does not become 0%, and may be restored to a state increased to 1.76%. That is, it may not be recovered to the original tensile deformation degree, but may be recovered to a state increased to 1.76%. Accordingly, the variation in hysteresis of the first cover substrate CS1 may be 1.76%.

Further, referring to FIG. 7B, as indicated by a dotted line, as the tensile strength of the second cover substrate CS2 increases during tension, the degree of tensile deformation increases. Specifically, the tensile strength increases from 0 MPa to 1.2 Mpa or more during tension, and accordingly, the degree of tensile deformation may also increase to 30%. In contrast, referring to FIG. 7B, as indicated by a solid line, the degree of tensile deformation decreases as the tensile strength decreases during the contraction of the second cover substrate CS2. Specifically, the tensile strength decreases from 1.2 Mpa or more to 0 MPa during tension, and accordingly, the degree of tensile deformation may gradually decrease. However, as shown in FIG. 7B, even if the tensile strength becomes 0 MPa during contraction, the degree of tensile deformation is not 0%, and may be restored to a state increased to 1.2%. That is, it may not be recovered to the original tensile deformation degree, but may be recovered to a state increased to 1.2%. Accordingly, the variation in hysteresis of the second cover substrate CS2 may be 1.2%.

As described above, the tensile modulus of the first cover substrate CS1 is higher than that of the second cover substrate CS2 so that the variation of the hysteresis of the second cover substrate CS2 may be lower than the variation of the hysteresis of the second cover substrate CS2. Further, in order to have a Hysteresis variation of 2% or less between the first cover substrate CS1 and the second cover substrate CS2, the tensile modulus of the first cover substrate CS1 and the tensile modulus of the second cover substrate CS2 may be 3.0 MPa to 7.0 MPa. Specifically, the tensile modulus of the first cover substrate CS1 may be 4.0 MPa to 7.0 MPa, and the tensile modulus of the second cover substrate CS2 may be 3.0 MPa to 5.5 MPa.

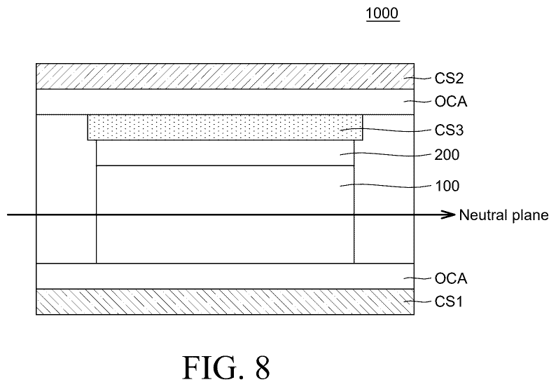

FIG. 8 is a view illustrating a neutral plane of a display device.

In addition, as described above, since the tensile modulus of the first cover substrate CS1 is higher than that of the second cover substrate CS2, as illustrated in FIG. 8, the neutral plane of the display device 1000 may be disposed inside the display panel 100.

Specifically, the neutral plane refers to a cross section in which the stress is zero because the tensile force and the compressive force are balanced when the external force acts on the structure. This cross section minimizes deformation within the structure and plays an important role in maintaining structural stability. The display device 1000 illustrated in FIG. 8 shows a structure designed to optimize the position of the neutral plane.

The first cover substrate CS1 is designed to have a higher tensile modulus than the second cover substrate CS2. The tensile modulus is a physical property that indicates how much a material can resist deformation against an external force, and a material with a high tensile modulus has a high resistance to deformation. The high tensile modulus of the first cover substrate CS1 is a major factor that causes the neutral plane to move toward the substrate. As a result, the neutral plane is formed at a position away from the second cover substrate CS2 having a relatively low rigidity and adjacent to the first cover substrate CS1.

The neutral plane is designed to overlap the inside of the display panel 100, that is, an area in which light emitting elements (e.g., organic light emitting elements, OLEDs) and transistors (e.g., thin film transistors, TFTs) are disposed. Since the main components of the display panel 100 are disposed close to the neutral plane, the tensile and compressive stresses to which the components are subjected are minimized even if structural deformation occurs due to an external force (e.g., bending, stretching, etc.).

The technical advantages of these designs can be explained as follows. When stretching or bending deformation is repeatedly applied, the light emitting element and the transistor located inside the display panel 100 are protected from stress generated by an external force. Since little deformation occurs near the neutral plane, the possibility of physical damage is significantly reduced for the light-emitting elements and transistors disposed in this area. This prevents problems such as cracks in the light emitting element, disconnection of the electrode, deterioration of the characteristics of the transistor, delamination, and the like, and prevents the performance of the display panel 100 from deteriorating.

The transistor is a main element required to control an electrical signal, and if the neutral plane design is not correct, the deformation shape is skewed to one side, and when physical damage occurs, the circuit resistance value changes and breaks occur, which may degrade the electrical characteristics of the entire display panel. To prevent this problem, the display device 1000 adopts a structure that precisely matches the neutral plane and the main components of the display panel 100.

In conclusion, the display device 1000 guides the neutral plane into the display panel 100 by using the high tensile modulus of the first cover substrate CS1, thereby effectively protecting the light emitting element and the transistor from deformation and stress. This design ensures long-term stability and reliability of the display device, and has important technical features that provide excellent performance and durability, especially in applications such as flexible displays.

Further, the third cover substrate CS3 has a tensile modulus lower than that of the second cover substrate CS2, and this characteristic is designed to perform a specific function as an upper protective layer of the display device 1000. For example, the third cover substrate CS3 may have a low tensile modulus in the range of 0.75 MPa to 1.5 MPa, and such a low tensile modulus increases the flexibility of the third cover substrate CS3 and may effectively absorb and alleviate mechanical stress generated in an external impact or deformation situation.

The third cover substrate CS3 is disposed on the upper end of the display device 1000 and is bonded to the touch panel 200 through the optical adhesive OCA. The third cover substrate CS3 having a low tensile modulus maintains the functionality of the touch panel 200 and protects the device from external impacts and scratches. Further, the third cover substrate CS3 is formed of a polymer film or a flexible material having high transparency, so that the touch sensitivity and accuracy can be maintained without affecting the optical performance of the display.

Hereinafter, a display device according to another embodiment of the present disclosure will be described. Since the display device according to the exemplary embodiment of the present disclosure and the display device according to another exemplary embodiment of the present disclosure differ only in the presence or absence of a cover coating layer, this will be described in detail.

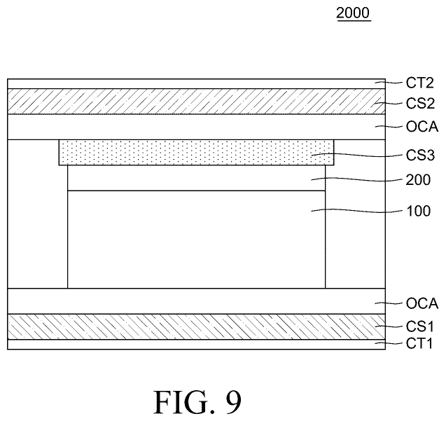

FIG. 9 is a cross-sectional view of a display device according to another embodiment of the present disclosure.

Referring to FIG. 9, a display device 2000 according to another embodiment of the present disclosure may further include at least one cover coating layer CT1 and CT2 on an outer surface of at least one cover substrate CS1 and CS2. Further, the coefficient of friction of the at least one cover coating layer CT1 and CT2 may be lower than the coefficient of friction of the at least one cover substrate CS1 and CS2.

The first cover coating layer CT1 is disposed at the lowermost end of the display device 2000 and is formed on the lower outer surface of the first cover substrate CS1. The first cover coating layer CT1 includes a reactive nano crosslinker, and may optimize the coefficient of friction resistance by adjusting the content and type of the nano crosslinker. Accordingly, stable slip characteristics are provided under the display device 2000 and stability during movement and use of the device is increased.

The material of the first cover coating layer CT1 is composed of a polymer-based material having low friction characteristics, and a reactive nano crosslinker is added to strengthen the material. The nano crosslinker improves the structural stability and durability of the material by forming a chemical bond within the polymer network. Typically, a silicone polymer, a fluorine-based coating agent, or a UV curable polyurethane may be used. These materials provide low surface energy to reduce frictional resistance, while maintaining mechanical strength and durability.

The first cover coating layer CT1 improves a lower slip characteristic so that the display device 2000 can stably operate on various surfaces. The low frictional resistance increases the mobility and handling convenience of the device and prevents damage due to contact with the surface. In addition, the structural reinforcement utilizing the nano crosslinker allows the slip characteristics to be maintained even when the device is used for a long time and provides both durability and reliability.

The second cover coating layer CT2 is located at the top of the display device 2000 and is formed on the upper outer surface of the second cover substrate CS2. The second cover coating layer CT2 optimizes the frictional resistance coefficient of the upper part by adjusting the content and type of the reactive nano crosslinker, and improves the slip characteristics to increase the external environment adaptability of the device. In addition, the second cover coating layer CT2 provides a function of protecting the device from scratch and external impact.

The second cover coating layer CT2 is made of a highly functional material that simultaneously provides transparency and durability, and includes a reactive nano crosslinker. A silicone-based coating agent, a UV curable polyurethane, or a fluoropolymer (e.g., PTFE, fluororesin) may be used as the main material. In particular, by introducing a polymer having self-healing properties, it can be designed to be restored when fine scratches or damage occur. nano crosslinker serves to increase the chemical bonding strength of the coating layer and strengthen durability and surface stability.

The second cover coating layer CT2 improves slip properties on the upper surface to provide resistance to external impact and scratches. For this reason, the surface state is maintained when the display device 2000 is used for a long time, and high sensitivity and accuracy are provided when a user's touch is input. In addition, the low frictional resistance characteristics improve the upper operability of the device and reinforce durability in an external environment. The introduction of material having self-healing properties provides additional advantages of prolonging the life of the device and reducing maintenance costs.

At least one cover coating layer CT1, CT2 serves as an important component to satisfy the performance required in a next-generation display environment by simultaneously providing Tacki-less characteristics and slip characteristics and durability that enhance the outer surface protection function of the display device 2000 and reduce surface stickiness.

Hereinafter, a display device according to still another embodiment of the present disclosure will be described. Since the display device according to the exemplary embodiment of the present disclosure and the display device according to another exemplary embodiment of the present disclosure differ only from the cover substrate, this will be described in detail.

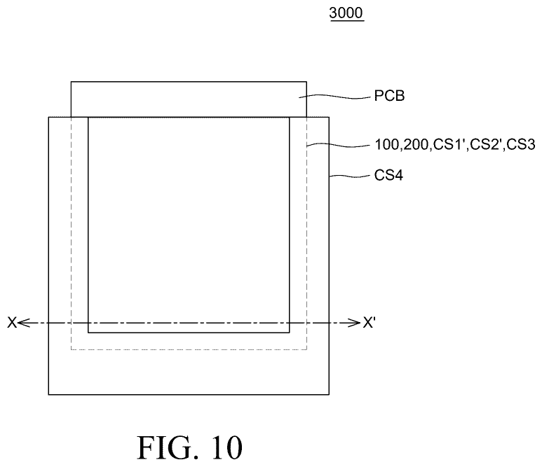

FIG. 10 is a plan view schematically illustrating a display device according to embodiments of the present disclosure.

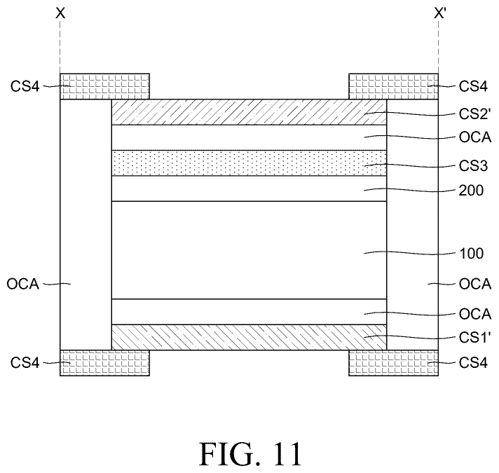

FIG. 11 is a cross-sectional view taken along line X-X′ illustrated in FIG. 10.

As illustrated in FIGS. 10 and 11, a display device 3000 according to still another exemplary embodiment of the present disclosure includes a fourth cover substrate CS4, and the fourth cover substrate CS4 reinforces external protection and structural stability of the display device 3000 through characteristics of having a tensile modulus higher than that of the first cover substrate CS1′. And sizes of the first cover substrate CS1′ and the second cover substrate CS2′ of the display device 3000 according to still another exemplary embodiment of the present disclosure may be the same as those of the display panel 100 and the touch panel 200, but are not limited thereto.

Specifically, the fourth cover substrate CS4 is disposed on the upper and lower outer sides of the display device 3000 to protect internal components (the display panel 100, the touch panel 200, the first cover substrate CS1′, the second cover substrate CS2′, and the third cover substrate CS3) from shocks, pressures, and environmental factors generated from the outside of the device. In addition, the high tensile modulus complements the overall rigidity of the device and maintains the mechanical stability of the device.

More specifically, the fourth cover substrate CS4 is located on the outer periphery of the second cover substrate CS2′ at the upper end of the display device 3000 and is coupled to these substrates by means of an optical adhesive (OCA). This reinforces the upper structure and minimizes mechanical damage when an external impact occurs on the upper part. And the fourth cover substrate CS4 is located on the outer periphery of the first cover substrate CS1′ at the lower end of the display device 3000 and is bonded to the internal components by means of the optical adhesive (OCA). At the bottom, the stability of the device is maintained, and the bottom is protected from mechanical shock and friction generated in the external environment. Further, as shown in FIG. 10, the fourth cover substrate CS4 is disposed not only at the upper and lower ends of the display device, but also at the left and right edges of the display device to surround the overall structure of the display device 3000. This arrangement makes it possible to respond to external shocks from the side.

The fourth cover substrate CS4 may be made of a material having excellent durability and strength, and is generally adopt tempered glass, ceramic, or a high-strength polymer (e.g., polycarbonate). In addition, a scratch-resistant coating or an anti-contaminant coating may be added to enhance surface properties. In particular, the fourth cover substrate CS4 maximizes resistance to mechanical shock by using a material having a high tensile modulus (e.g., 7 MPa).

The fourth cover substrate CS4 greatly improves the structural stability of the display device 3000 through a high tensile modulus. Damage due to external impact and pressure is prevented, and the life of the internal component is extended. In addition, the load of the device is evenly distributed to minimize mechanical deformation and allow the device to operate stably.

The outer protection function of the fourth cover substrate CS4 is particularly suitable for devices that are frequently exposed to an external environment, such as a wearable device, and greatly improves the reliability and durability of the device. In addition, each component is completely fixed through bonding with the optical adhesive (OCA), and structural integrity is maintained.

Accordingly, the display device 3000 according to another exemplary embodiment of the present disclosure guarantees resistance to external impacts and environmental factors of the display device 3000 based on a high tensile modulus and durability, and acts as an essential protective component suitable for next-generation display and wearable technology.

The exemplary embodiments of the present disclosure can also be described as follows:

In order to achieve the objects as described above, according to an aspect of the present disclosure, a display device includes a display panel comprising a first stretchable substrate, a plurality of sub-pixels spaced apart from each other on the first stretchable substrate, a plurality of stretchable connection lines connecting the sub-pixels, and a second stretchable substrate on the plurality of sub-pixels and the plurality of connection lines, and at least one cover substrate disposed outside the display panel, and the tensile modulus of the cover substrate is higher than that of the first stretchable substrate and the second stretchable substrate.

According to another feature of the present disclosure, the display device includes a touch panel disposed on the display panel, a first cover substrate disposed on a lower surface of the display panel, and a second cover substrate disposed on the touch panel, and the tensile modulus of the first cover substrate is higher than that of the second cover substrate.

According to another feature of the present disclosure, the tensile modulus of at least one cover substrate is 3.0 MPa to 7.0 MPa.

According to another feature of the present disclosure, at least one cover coating layer is disposed on the outer surface of the at least one cover substrate, and the coefficient of friction of the cover coating layer is lower than the coefficient of friction of the cover substrate.

According to another feature of the present disclosure, the cover coating layer includes a first cover coating layer disposed on the outer surface of the first cover substrate and a second cover coating layer disposed on the outer surface of the second cover substrate.

According to another feature of the present disclosure, at least one cover substrate includes a third cover substrate disposed between the touch panel and the second cover substrate, and the tensile modulus of the third cover substrate is lower than that of the second cover substrate.

According to another feature of the present disclosure, at least one cover substrate includes a plurality of fourth cover substrates in contact with an outer peripheral area of the first cover substrate and an outer peripheral area of the second cover substrate, and the tensile modulus of the fourth cover substrate is higher than that of the first cover substrate.

According to another feature of the present disclosure, the fourth cover substrate is also provided at left and right edges of the display device.

According to another feature of the present disclosure, the at least one cover coating layer includes a reactive nano crosslinker.

According to another feature of the present disclosure, tensile modulus of the first stretchable substrate and tensile modulus of the second stretchable substrate are equal to or less than 1 MPa.

According to another feature of the present disclosure, the neutral plane of the display device is located inside the display panel.

A display device according to another exemplary embodiment of the present disclosure includes a first cover substrate, a stretchable display panel, a stretchable touch panel on the stretchable display panel, and a second cover substrate on the stretchable touch panel, wherein the tensile modulus of the first cover substrate and the second cover substrate is higher than the tensile modulus of the stretchable substrate included in the stretchable display panel.

According to another feature of the present disclosure, the tensile modulus of each of the first cover substrate and the second cover substrate is 3.0 MPa to 7.0 MPa.

According to another feature of the present disclosure, the display device comprises a first cover coating layer positioned below the first cover substrate and a second cover coating layer disposed above the second cover substrate, wherein the coefficient of friction of the first cover coating layer and the second cover coating layer is lower than the coefficient of frictions of the first cover substrate and the second cover substrate.

According to another feature of the present disclosure, the display device includes a third cover substrate disposed between the stretchable touch panel and the second cover substrate, wherein the tensile modulus of the third cover substrate is lower than that of the second cover substrate.

According to another feature of the present disclosure, the display device includes a plurality of fourth cover substrates in contact with the edge of the first cover substrate and the edge of the second cover substrate, and wherein the tensile modulus of the fourth cover substrate is higher than that of the first cover substrate.

According to another feature of the present disclosure, the first cover coating layer and the second cover coating layer include reactive nano crosslinkers.

According to another feature of the present disclosure, a tensile modulus of the stretchable substrate is equal to or less than 1 MPa.

According to another feature of the present disclosure, the neutral plane of the display device is located inside the stretchable display panel.

The exemplary embodiments of the present disclosure can be further described as follows:

In certain embodiments, a display device may include a first cover substrate CS1 that provides structural support for the device. A display panel 100 may be disposed on the first cover substrate CS1. The display panel 100 may include a first stretchable substrate 111, a plurality of sub-pixels disposed on the first stretchable substrate 111, a plurality of stretchable connection lines 181, 182 connecting the sub-pixels, and a second stretchable substrate 112 disposed on the plurality of sub-pixels and the plurality of stretchable connection lines. A second cover substrate CS2 may be disposed on the display panel, and a third cover substrate CS3 may be positioned between the display panel 100 and the second cover substrate CS2. In some implementations as shown in FIG. 2, a planar area of the first cover substrate and a planar area of the second cover substrate are each greater than a planar area of the third cover substrate so that the third cover substrate is located within the boundary defined by the first and second cover substrates in plan view.

In certain configurations, a footprint of the first cover substrate and a footprint of the second cover substrate may each be greater than a footprint of the third cover substrate (see FIG. 2). By employing cover substrates having larger footprints than the third cover substrate, the device may achieve controlled mechanical behavior and improved handling at boundary regions.

In some embodiments, the first cover substrate and the second cover substrate may each have a tensile modulus higher than that of the third cover substrate. The relative tensile modulus differences may allow the third cover substrate to deform more readily than the first and second cover substrates under mechanical loading, thereby supporting the intended flexibility and mechanical characteristics of the display panel assembly.

The display device may additionally include a fourth cover substrate CS4 disposed at a peripheral area of the first cover substrate, the second cover substrate, or both. The fourth cover substrate may be located along or adjacent to outer regions of the device and may serve to reinforce peripheral portions of the display assembly or enhance external protection depending on the intended implementation.

In certain embodiments, the fourth cover substrate may overlap the third cover substrate in plan view (see FIG. 11). Such overlap may occur where the fourth cover substrate extends inward from a peripheral area toward a region occupied by the third cover substrate, thereby partially covering or reinforcing the third cover substrate.

The fourth cover substrate may have a tensile modulus greater than that of the third cover substrate. By selecting a material for the fourth cover substrate with a higher tensile modulus than the material of the third cover substrate, the peripheral region of the display device may be strengthened while the central region containing the third cover substrate maintains compliant mechanical behavior.

In some embodiments, the first cover substrate and the second cover substrate may each extend beyond a peripheral area of the display panel in plan view. This extended portion may provide a margin region surrounding the display panel that contributes to improved handling, enhanced environmental sealing, or more robust integration of surrounding components.

The third cover substrate may have a planar area corresponding to a footprint of the display panel (see FIG. 11). For example, the third cover substrate may be sized so that its lateral extent aligns with or matches the lateral outline of the display panel, thereby supporting or protecting primarily the central active portion of the display device.

The display device may further include a first optical adhesive disposed between the first cover substrate and the display panel, and a second optical adhesive disposed between the second cover substrate and the third cover substrate. These optical adhesives may facilitate attachment between adjacent layers while maintaining desirable optical transmission and mechanical compliance.

In some embodiments, at least one of the first cover substrate and the second cover substrate may include a coating layer disposed on an exterior surface thereof. The coating layer may comprise a polymer including reactive nano crosslinkers. Incorporation of nano crosslinkers may enhance durability, scratch resistance, or frictional properties of the exterior surfaces of the display device.

The first stretchable substrate and the second stretchable substrate may each have a tensile modulus lower than the tensile moduli of the first cover substrate and the second cover substrate. This modulus hierarchy may allow the stretchable substrates to undergo greater deformation during bending or stretching of the display device, while the cover substrates maintain structural stability and provide external protection.

In some embodiments, when the display device is bent, a neutral plane may be formed within the structure of the device. The neutral plane may pass through the display panel in a thickness direction, such that the zero-strain region during bending is located within the multilayer display panel itself rather than within one of the outer cover substrates (see FIG. 8). Positioning the neutral plane within the display panel may enhance mechanical reliability during repeated bending or stretching operations.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are exemplary in all aspects and are not limited. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel comprising a first stretchable substrate, a plurality of sub-pixels spaced apart from each other on the first stretchable substrate, a plurality of stretchable connection lines connecting the sub-pixels, and a second stretchable substrate on the plurality of sub-pixels and the plurality of stretchable connection lines; and
at least one cover substrate disposed outside the display panel,
wherein a tensile modulus of the at least one cover substrate is greater than a tensile modulus of the first stretchable substrate and a tensile modulus of the second stretchable substrate.

2. The display device according to claim 1, further comprising:
a touch panel disposed on the display panel,
wherein the at least one cover substrate comprises a first cover substrate disposed on a lower surface of the display panel and a second cover substrate disposed on the touch panel,
wherein a tensile modulus of the first cover substrate is greater than a tensile modulus of the second cover substrate.

3. The display device according to claim 1, wherein the tensile modulus of the at least one cover substrate is 3.0 MPa to 7.0 MPa.

4. The display device according to claim 2, wherein at least one cover coating layer is disposed on the outer surface of the at least one cover substrate, and
wherein a coefficient of friction of the at least one cover coating layer is lower than a coefficient of friction of the at least one cover substrate.

5. The display device according to claim 4, wherein the at least one cover coating layer includes a first cover coating layer disposed on an outer surface of the first cover substrate and a second cover coating layer disposed on an outer surface of the second cover substrate.

6. The display device according to claim 2, wherein the at least one cover substrate further includes a third cover substrate disposed between the touch panel and the second cover substrate, and
wherein a tensile modulus of the third cover substrate is lower than a tensile modulus of the second cover substrate.

7. The display device according to claim 2, wherein the at least one cover substrate further includes a plurality of fourth cover substrates contacting an outer peripheral area of the first cover substrate and an outer peripheral area of the second cover substrate, and
wherein the tensile modulus of the fourth cover substrate is greater than the tensile modulus of the first cover substrate.

8. The display device according to claim 7, wherein the fourth cover substrate is also provided at left and right edges of the display device.

9. The display device according to claim 4, wherein the at least one cover coating layer includes a reactive nano crosslinker.

10. The display device according to claim 1, wherein a tensile modulus of the first stretchable substrate and a tensile modulus of the second stretchable substrate are equal to or less than 1 MPa.

11. The display device according to claim 2, wherein a neutral plane of the display device is disposed inside the display panel.

12. A display device comprising:
a first cover substrate;
a stretchable display panel disposed on the first cover substrate;
a stretchable touch panel disposed on the stretchable display panel; and
a second cover substrate disposed on the stretchable touch panel,
wherein a tensile modulus of the first cover substrate and a tensile modulus of the second cover substrate are greater than a tensile modulus of a stretchable substrate included in the stretchable display panel.

13. The display device according to claim 12, wherein the tensile modulus of the first cover substrate and the tensile modulus of the second cover substrate are 3.0 MPa to 7.0 MPa.

14. The display device according to claim 12, further comprising:
a first cover coating layer positioned below the first cover substrate; and
a second cover coating layer disposed above the second cover substrate,
wherein a coefficient of friction of the first cover coating layer and a coefficient of friction of the second cover coating layer are each lower than a coefficient of friction of the first cover substrate and a coefficient of friction of the second cover substrate.

15. The display device according to claim 12, further comprising:
a third cover substrate disposed between the stretchable touch panel and the second cover substrate,
wherein a tensile modulus of the third cover substrate is lower than a tensile modulus of the second cover substrate.

16. The display device according to claim 12, further comprising:
a plurality of fourth cover substrates contacting the edge of the first cover substrate and the edge of the second cover substrate,
wherein the tensile modulus of the fourth cover substrate is higher than that of the first cover substrate.

17. The display device according to claim 14, wherein the first cover coating layer and the second cover coating layer include reactive nano crosslinkers.

18. The display device according to claim 12, wherein a tensile modulus of the stretchable substrate is equal to or less than 1 MPa.

19. The display device according to claim 12, wherein a neutral plane of the display device is disposed inside the stretchable display panel.

20. A display device comprising:
a first cover substrate;
a display panel on the first cover substrate, the display panel including a first stretchable substrate, a plurality of sub-pixels disposed on the first stretchable substrate, a plurality of stretchable connection lines connecting the sub-pixels, and a second stretchable substrate on the plurality of sub-pixels and the plurality of stretchable connection lines;
a second cover substrate on the display panel; and
a third cover substrate between the display panel and the second cover substrate,
wherein a planar area of the first cover substrate and a planar area of the second cover substrate are each greater than a planar area of the third cover substrate.

21. The display device of claim 20,
wherein a footprint of the first cover substrate and a footprint of the second cover substrate are each greater than a footprint of the third cover substrate.

22. The display device of claim 20,
wherein a tensile modulus of the first cover substrate and a tensile modulus of the second cover substrate are each higher than a tensile modulus of the third cover substrate.

23. The display device of claim 20, further comprising a fourth cover substrate disposed at a peripheral area of the first cover substrate, the second cover substrate, or both.

24. The display device of claim 23, wherein the fourth cover substrate overlaps the third cover substrate in plan view.

25. The display device of claim 23, wherein the fourth cover substrate has a tensile modulus greater than a tensile modulus of the third cover substrate.

26. The display device of claim 20, wherein the first cover substrate and the second cover substrate each extend beyond a peripheral area of the display panel in plan view.

27. The display device of claim 20, wherein the third cover substrate has a planar area corresponding to a footprint of the display panel.

28. The display device of claim 20, further comprising:
a first optical adhesive between the first cover substrate and the display panel; and
a second optical adhesive between the second cover substrate and the third cover substrate.

29. The display device of claim 20, wherein at least one of the first cover substrate and the second cover substrate includes a coating layer disposed on an exterior surface thereof, and
wherein the coating layer comprises a polymer including reactive nano crosslinkers.

30. The display device of claim 20, wherein the first stretchable substrate and the second stretchable substrate each have a tensile modulus lower than the tensile moduli of the first cover substrate and the second cover substrate.

31. The display device of claim 20, wherein a neutral plane formed during bending of the display device passes through the display panel in a thickness direction.
